(19) United States
(12) Patent Application Publication
(10) Pub. No.: US 2022/0228293 A1
(43) Pub. Date: Jul. 21, 2022

(54) DEPOSITION OF ALPHA-GALLIUM OXIDE THIN FILMS

(71) Applicant: Elham RAFIE BORUJENY, Edmonton (CA)

(72) Inventor: Elham RAFIE BORUJENY, Edmonton (CA)

(21) Appl. No.: 17/576,784

(22) Filed: Jan. 14, 2022

Related U.S. Application Data
(60) Provisional application No. 63/137,874, filed on Jan. 15, 2021.

(51) Int. Cl. C30B 25/18; H01L 21/02; C23C 16/40; C23C 16/455; C30B 29/16

(52) U.S. Cl. CPC C30B 25/18; H01L 21/0242; H01L 21/02458; H01L 21/02513; H01L 21/02565; C30B 29/16; H01L 21/0262; C23C 16/40; C23C 16/45553; C23C 16/45536; H01L 21/02598

(57) ABSTRACT

A method for forming alpha-gallium oxide (α-Ga₂O₃) on GaN-compatible substrates uses an epitaxial deposition process comprising (a) forming about one monolayer of wurtzite gallium nitride (w-GaN) on the substrate; (b) reacting the said monolayer of w-GaN with an oxygen precursor to form about one monolayer of α-Ga₂O₃ on the substrate; (c) repeating steps (a) and (b) to form one or more additional monolayers of α-Ga₂O₃ on the substrate.

### CROSS-REFERENCE TO RELATED APPLICATION

This application claims priority to U.S. Provisional Patent Application No. 63/137,874, filed on Jan. 15, 2021, the entire disclosure of which is incorporated by reference herein in its entirety for all purposes.

### FIELD OF THE INVENTION

The present invention relates to forming semiconductor thin films, using epitaxial deposition processes.

### BACKGROUND OF THE INVENTION

Research into new materials for power electronic devices has emerged as an inseparable part of sustainable development and efficient handling of electrical energy during the past three decades. Such power devices may convert DC power generated by solar cells and fuel cells to AC power, thereby making it usable by consumers. Alternatively, such power devices may convert AC power supplied by a provider to DC power, thereby making it usable in charging the battery of an electric car or a portable electronic device.

Wide bandgap semiconductors such as GaN (gallium nitride) and SiC (silicon carbide) have been considered as candidate materials for power devices to overcome the limitations of their traditional predecessors (such as Si (silicon) and GaAs (gallium arsenide)) in meeting the growing needs and the stringent requirements of the high energy demand society today.

Thanks to nearly three decades of research on GaN electronics, strategies for GaN heteroepitaxy on common substrates (such as sapphire, Si, SiC, diamond, and even β-Ga₂O₃) as well as n- and p-type doping of GaN have been successfully developed and are being used in commercial power conversion devices today (see below References no. 10-12). Wurtzite GaN (w-GaN) with a hexagonal crystal structure (belonging to the space group P6₃mc) is the widely used polymorph in GaN electronic devices.

During the past few years, Ga₂O₃(gallium oxide) has been proposed as an alternative material for such semiconductor devices promising to offer higher efficiency in power handling than the materials in use today and expected to compete with and complement the outstanding properties of GaN as the frontrunner material for power electronic devices (see References no. 1-5). In addition to power applications, Ga₂O₃ expands the wavelength span of optoelectronic devices to the deep UV (see below Reference no 3).

The properties of Ga₂O₃ depend on its crystal structure (see below Reference no. 3). Most attention has been devoted to monoclinic β-Ga₂O₃ as the most stable polymorph (belonging to the space group C2/m). With the recent availability of β-Ga₂O₃ bulk wafers (grown from the melt at high temperatures, ca. 1800° C.) (see below References no. 1, and 3-5) homoepitaxial thin films of the β-Ga₂O₃ polymorph can be deposited on its native substrate (see below References no. 1, 3, and 4). However, there are currently a number of challenges that limit the development of β-Ga₂O₃ electronic devices including inherent complexities in its crystal structure, limited success in heteroepitaxial growth of β-Ga₂O₃ on foreign substrates (see below Reference no. 6), and the lack of successful p-type doping of β-Ga₂O₃ (see below Reference no. 7).

On the other hand, the rhombohedral α-Ga₂O₃ polymorph (belonging to the space group R3̅c that can be projected on a hexagonal coordinate system as well) can exist at ambient to high temperatures and pressures, and has superior properties to β-Ga₂O₃ for both power handling and optoelectronics, including a larger bandgap, larger breakdown voltage, larger refractive index, and larger dielectric constant as well as an ˜20% smaller effective mass of electrons compared to β-Ga₂O₃ (see below References no. 3, 6, 8 and 9).

In order to implement Ga₂O₃ in next-generation electronic devices, there is a need in the art for forming a thin film comprising α-Ga₂O₃, preferably with relatively low amounts of other Ga₂O₃ polymorphs (such as β-Ga₂O₃) and impurities, and using an energy-efficient fabrication process.

### SUMMARY OF THE INVENTION

The present invention relates to a deposition strategy for obtaining high quality α-Ga₂O₃ on GaN-compatible substrates with atomic level control over the crystal structure. Without restriction to a theory, it is believed that sustained hexagonal scaffolding at the atomic scale, as a result of using a GaN-mediated Ga₂O₃ deposition approach described herein, enabled as an example by plasma-enhanced ALD, plays a unique role in steering the atoms to form the crystal structure of α-Ga₂O₃ at a low thermal budget. This approach minimizes the formation of β-Ga₂O₃ domains and hinders formation of a mixed-phase material. It also makes integration of GaN and Ga₂O₃ components on a monolithic substrate possible and facilitates fast-track exploitation of GaN technology advancements (such as thermal management and doping) for development of Ga₂O₃ electronics.

In one aspect, the present invention comprises a method for forming a thin film comprising alpha-gallium oxide (α-Ga₂O₃) on a GaN-compatible substrate in a reaction chamber, the method using an epitaxial deposition process comprising the steps of:
(a) forming a layer of wurtzite gallium nitride (w-GaN) on the substrate;
(b) reacting the layer of w-GaN with an oxygen precursor to form a layer of α-Ga₂O₃ on the substrate, and optionally, subsequently purging the reaction chamber with an inert gas (e.g., argon) to remove any excess of the oxygen precursor and/or reaction byproducts from the reaction chamber; and
(c) repeating steps (a) and (b) to form one or more additional layer(s) of α-Ga₂O₃ on the substrate.

In embodiments, the layer of w-GaN is a single monolayer of w-GaN, and the layer of α-Ga₂O₃ is a single monolayer of α-Ga₂O₃.

In embodiments, the epitaxial deposition process may comprise an atomic layer deposition (ALD) process comprising the sequential steps of:
(i) contacting the substrate with a gallium precursor, such as triethylgallium (TEG) gas, to form a layer of gallium precursor on the substrate, and optionally, subsequently purging the reaction chamber with an inert gas (e.g., argon) to remove any excess of the gallium precursor and/or reaction byproducts from the reaction chamber;
(ii) reacting the layer of gallium precursor with a nitrogen precursor, such as a N₂/H₂ forming gas plasma, to form the layer of wurtzite gallium nitride (w-GaN) on the substrate, and optionally, subsequently purging the reaction chamber with an inert gas (e.g., argon) to remove any excess of the nitrogen precursor and/or reaction byproducts from the reaction chamber;
(iii) reacting the layer of w-GaN with an oxygen precursor, such as oxygen plasma, to form the layer of α-Ga₂O₃ on the substrate; and
(iv) repeating steps (i) to (iii) to form one or more additional layers of α-Ga₂O₃ on the substrate, until a desired thickness of the thin film on the substrate is formed.

In embodiments, the layer of gallium precursor is a single monolayer of gallium precursor, the layer of w-GaN is a single monolayer of w-GaN, and each of the layers of α-Ga₂O₃ is a single monolayer of α-Ga₂O₃.

In embodiments, the GaN-compatible substrate is a non-native substrate, which may be sapphire, and more particularly, c-plane sapphire.

In embodiments, the thin film comprises less than 10% β-Ga₂O₃, by ratio of mass of β-Ga₂O₃ to mass of α-Ga₂O₃ and β-Ga₂O₃, collectively.

In embodiments, the method may be performed at a temperature of less than about 500° C., and preferably less than about 300° C., such as 277° C., which is relatively low in the context of crystalline material growth. The w-GaN deposition process, which in some embodiments may be achieved by using atomic layer deposition, forms a sacrificial w-GaN layer. Within the w-GaN deposition process, which in some embodiments may be plasma-enhanced, a highly symmetric atomic scale scaffold of gallium atoms is created by taking advantage of the sacrificial w-GaN layer as an intermediate step during α-Ga₂O₃ growth. Establishing the scaffold together with the use of highly reactive plasma species allow this GaN-mediated α-Ga₂O₃ deposition process to be performed at low thermal budget while resulting in a highly oriented α-Ga₂O₃ thin film with vanishing amounts of nitrogen and carbon impurities as well as a larger bandgap and larger refractive index compared to the conventionally deposited Ga₂O₃.

In another aspect, the invention comprises a thin film of α-Ga₂O₃ formed by atomic layer deposition, and specifically a thin film formed by a method described herein. In some embodiments, the thin film is formed at a process temperature of less than about 500° C., and preferably less than about 300° C.

Embodiments of the invention may be useful for development of high performance and energy-efficient α-Ga₂O₃ electronics, advancing n-type and p-type doping of α-Ga₂O₃, and integrating complementary GaN and α-Ga₂O₃ semiconducting components on a single monolithic substrate to achieve the superior functionalities needed to meet the emerging requirements of modem power handling circuitries (including decreased energy loss, size, weight and cost).

A low temperature GaN-compatible deposition technology for Ga₂O₃ may be a key enabling technology for wide bandgap semiconductors, leading to energy-efficient electronic devices, not only in performance but also an energy-efficient fabrication process.

### BRIEF DESCRIPTION OF THE DRAWINGS

In the drawings, like elements may be assigned like reference numerals. The drawings are not necessarily to scale, with the emphasis instead placed upon the principles of the present invention. Additionally, each of the embodiments depicted are but one of a number of possible arrangements utilizing the fundamental concepts of the present invention.

FIGS. 1A and 1B show a monolayer of w-GaN along the c-axis (FIG. 1A) and perpendicular to the c-axis (FIG. 1B). In FIG. 1A, dashed lines show the atomic scale scaffold of Ga atoms for visual reference.

FIGS. 1C and 1D show a slice of α-Ga₂O₃ along the c-axis (FIG. 1C) and perpendicular to the c-axis (FIG. 1D). In FIG. 1C, dashed lines show the atomic scale scaffold of Ga atoms for visual reference.

FIGS. 2A, 2B and 2C show out-of-plane coupled XRD patterns and schematic of the deposition steps for conventional GaN deposition (FIG. 2A), conventional Ga₂O₃ deposition (FIG. 2B) and GaN-mediated Ga₂O₃ deposition in accordance with the present invention (FIG. 2C). In these Figures, the XRD pattern of the bare sapphire substrate is included as a reference to better distinguish thin film peaks in the patterns.

FIGS. 3A through 3K show transmission electron microscopy (TEM) analysis results for a GaN-mediated in-situ oxidized Ga₂O₃ film of the present invention, as follows.

FIG. 3A is a high-resolution transmission electron microscopy (HRTEM) image.

FIGS. 3B to 3G are energy-dispersive X-ray spectroscopy (EDS) intensity maps obtained in scanning transmission electron microscopy (STEM) mode, without background subtraction obtained with a high-angle annular dark-field (HAADF) imaging detector (FIG. 3B), and with background subtraction obtained with EDS detectors to show spectra of aluminum (FIG. 3C), gallium (FIG. 3D), oxygen (FIG. 3E), nitrogen (FIG. 3F), and carbon (FIG. 3G).

FIG. 3H is an atomic resolution STEM image obtained with a HAADF imaging detector.

FIG. 3I is the same image shown in FIG. 3H after using a combination of high-pass and radial Wiener filters to highlight atomic columns.

FIG. 3J is a nano-beam electron diffraction pattern of the Ga₂O₃ film.

FIG. 3K is a nano-beam electron diffraction pattern of the sapphire substrate.

FIG. 4 shows optical constants of the GaN-mediated in-situ oxidized Ga₂O₃ film of the present invention, compared to two reference films after equal number of triethylgallium (TEG) doses. The values of bandgap and refractive index at the photon energy of 1.96 eV (corresponding to the wavelength of 632.8 nm) are listed for comparison.

FIG. 5 shows a table of non-limiting examples of gallium precursors that may be used in the method of the present invention.

FIG. 6 shows a table of non-limiting examples of oxygen precursors that may be used in the method of the present invention.

FIG. 7 shows a schematic depiction of an embodiment of a method of the present invention for forming a thin film comprising gallium oxide (α-Ga₂O₃) on a GaN-compatible substrate.

### DETAILED DESCRIPTION OF EMBODIMENTS OF THE INVENTION

### Definitions

The invention relates to formation of semiconductor thin films using an epitaxial deposition process. Any term or expression not expressly defined herein shall have its commonly accepted definition understood by a person skilled in the art. As used herein, the following terms have the following meanings.

“Atomic layer deposition” or “ALD” is a subclass of chemical vapor deposition, used to deposit thin films onto a substrate. ALD typically involves the sequential use of gas phase reactants, and/or plasma phase reactants, and surface chemical processes.

“Epitaxial deposition process”, as used herein, refers to a process that involves placing a substrate in a reaction chamber, and introducing one or more precursor (reactant) materials into the reaction chamber, such that the precursor(s) or their reaction product(s), deposit on the substrate to form a non-amorphous, crystalline layer having defined crystallographic orientation(s) relative to the underlying layer(s). In non-limiting embodiments, the epitaxial deposition process may comprise chemical vapor deposition (CVD) processes, physical vapor deposition (PVD) processes, or any other suitable deposition techniques as are known to a person skilled in the art of forming thin films. Chemical vapor deposition (CVD) processes may be performed using a variety of techniques known to a person skilled in the art, with non-limiting embodiments including metal-organic CVD (MOCVD), mist CVD, low pressure CVD, atmospheric CVD, plasma-assisted CVD (also referred to as plasma-enhanced CVD), photo-assisted CVD, molecular layer deposition (MLD), and atomic layer deposition (ALD) including spatial ALD, thermal ALD, plasma-assisted ALD (also referred to as plasma-enhanced ALD), and photo-assisted ALD. Metal-organic vapor phase epitaxy (MOVPE), halide vapor phase epitaxy (HVPE) and liquid phase epitaxy (LPE) may also be used. Physical vapor deposition (PVD) processes may be performed using a variety of sputtering techniques known to a person skilled in the art, with non-limiting embodiments including ion beam deposition, reactive sputtering, magnetron sputtering, and RF diode sputtering. Physical vapor deposition (PVD) processes may also be performed using a variety of evaporation techniques known to a person skilled in the art, with non-limiting embodiments including thermal evaporation, c-beam evaporation, pulsed laser deposition (PLD), and molecular beam epitaxy (MBE) including reactive MBE.

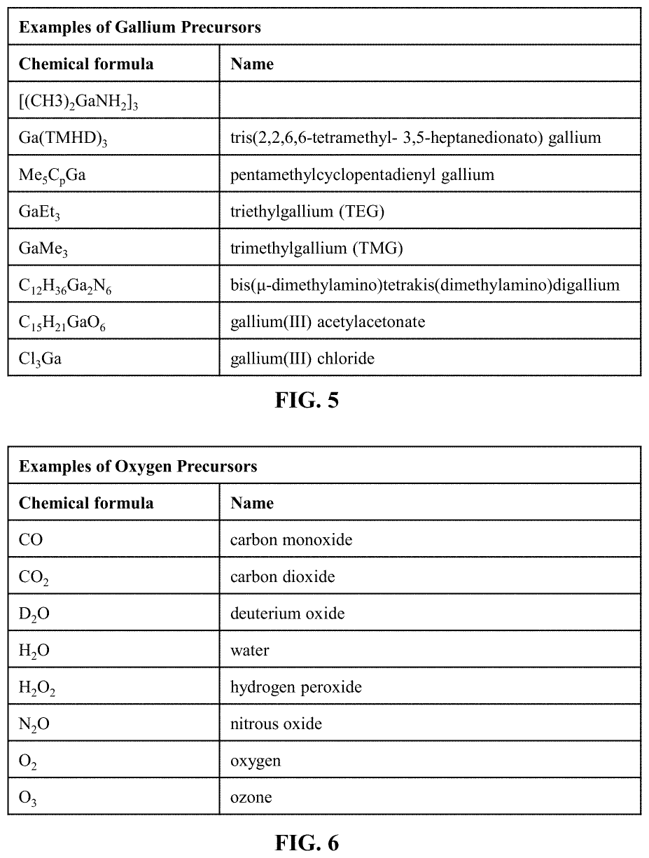

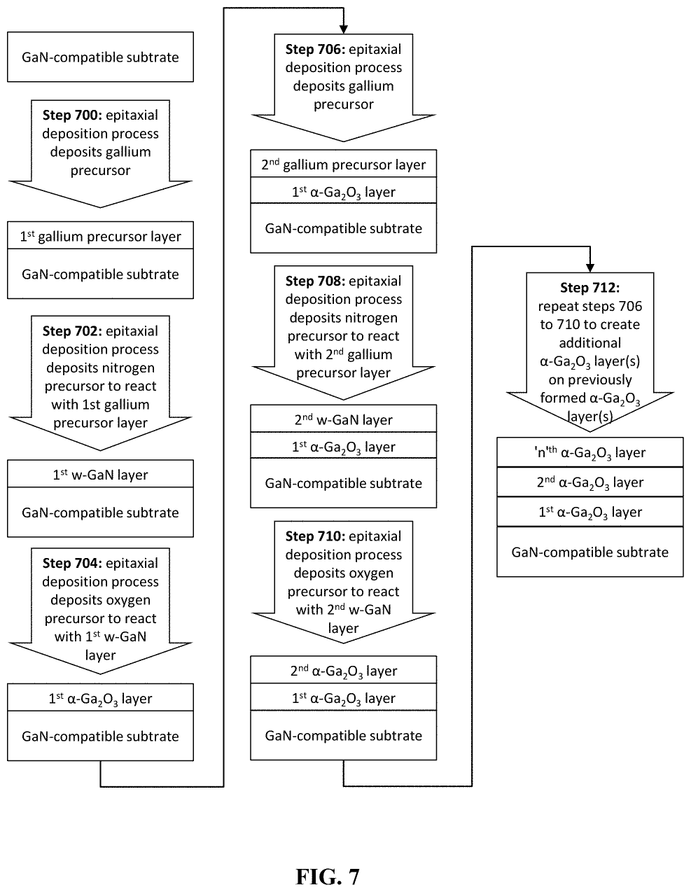

“Gallium precursor”, as used herein, refers to a substance comprising gallium atoms, which is suitable for use as reactant in an epitaxial deposition process. In non-limiting embodiments, including embodiments where the epitaxial deposition process is an atomic layer deposition process, the gallium precursor may comprise one or a combination of the substances shown in the table of FIG. 5.

“Monolayer”, as used herein, refers to a single layer of atoms, or molecules.

“Nitrogen precursor”, as used herein, refers to a substance comprising nitrogen atoms, which is suitable for use as a reactant in an epitaxial deposition process. In non-limiting embodiments, including embodiments where the epitaxial deposition process is an atomic layer deposition process, the nitrogen precursor may comprise one or a combination of nitrogen (N₂) gas or plasma, ammonia (NH₃) gas or plasma, or a N₂/H₂ forming gas or plasma.

“GaN-compatible substrate”, as used herein, refers to a substrate (e.g., a wafer, a membrane, a multilayer, or a laminated structure) comprising a material other than α-Ga₂O₃ (i.e., a “non-native substrate”) and/or α-Ga₂O₃ (i.e., a “native substrate”). In embodiments, the non-native substrate may comprise sapphire, Si, SiC, or diamond, or any other suitable substrate known in the art.

“N₂/H₂ forming gas plasma”, as used herein, refers to a plasma formed from a mixture of nitrogen gas (Nz) and hydrogen gas (H₂). In non-limiting embodiments, the N₂/H₂ forming gas plasma is formed from a mixture of 95% N₂ gas and 5% Hz gas, by volume. In other embodiments, the N₂/H₂ forming gas plasma may be formed from a mixture of N₂ gas and H₂ gas having a different volumetric ratio of N₂ gas and H₂ gas. It is within the skill of a person skilled in the art of thin film deposition to select a suitable volumetric ratio of N₂ gas and H₂ gas to react with a gallium precursor to form w-GaN. Usually, the amount of H₂ gas is selected to be less than about 5.7% by volume to avoid the risk of spontaneous or hazardous combustion of H₂ gas.

“Oxygen precursor”, as used herein, refers to a substance comprising oxygen atoms, which is suitable for use as reactant to react with wurtzite gallium nitride (w-GaN) to form α-Ga₂O₃ in an epitaxial deposition process. In non-limiting embodiments, including embodiments where the epitaxial deposition process is an atomic layer deposition process, the oxygen precursor may comprise one or a combination of the substances shown in the table of FIG. 6.

### Method of the Present Invention

Embodiments of the invention comprise a novel, self-regulated process, using an epitaxial deposition process, for controlling Ga₂O₃ crystallinity to achieve α-Ga₂O₃ through stepwise in-situ oxidation of w-GaN. In particular embodiments, the epitaxial deposition process is an atomic layer deposition process, involving in-situ plasma-enhanced oxidation of w-GaN.

FIG. 7 shows a schematic depiction of an embodiment of a method of the present invention for forming a thin film comprising gallium oxide (α-Ga₂O₃) on a GaN-compatible substrate. A GaN-compatible substrate is provided, and placed in a reaction chamber for an epitaxial deposition process. Steps (700) and (702) are directed to forming a first layer (e.g., a monolayer) of w-GaN on the substrate. In this embodiment, at step (700), the epitaxial deposition process is used to deposit a gallium precursor on the substrate to form a first layer (e.g., a monolayer) of gallium precursor on the substrate. At step (702), the epitaxial deposition process is used to deposit a nitrogen precursor on the first layer of gallium precursor, and react therewith, to form a first layer (e.g., a monolayer) of w-GaN on the substrate. In this embodiment, the introduction of the gallium precursor and the nitrogen precursor into the reaction chamber are sequential, and the nitrogen precursor reacts with the first gallium precursor layer on the surface of the substrate. In other embodiments (e.g., using chemical vapor deposition), the introduction of the gallium precursor and the nitrogen precursor into the reaction chamber may be simultaneous to form the first layer of w-GaN on the substrate. In either case, the formed layer of w-GaN provides a highly symmetric atomic scale scaffold of gallium atoms, but is sacrificed in the following step to form the highly oriented layer of α-Ga₂O₃ on the substrate.

Step (704) is directed to reacting the layer of w-GaN on the substrate with an oxygen precursor to form a layer (e.g., a monolayer) of α-Ga₂O₃ on the substrate. In this embodiment, the epitaxial deposition process is used to deposit an oxygen precursor on the first layer of w-GaN, and react therewith, to form a first layer of α-Ga₂O₃ on the substrate.

Steps (706) to (710) are a repetition of steps (700) to (704), performed in respect to the substrate with the first layer of α-Ga₂O₃ formed thereon as a result of step (704). These steps are directed to forming an additional layer (e.g., a monolayer) of α-Ga₂O₃ on the substrate. As indicated by step (712), steps (706) to (710) may be repeated as many times as desired to create additional layers (e.g., monolayers) of α-Ga₂O₃ on the substrate, with each repetition forming one such layer.

In one embodiment, α-Ga₂O₃ is formed on a GaN-compatible substrate in a reaction chamber, using ALD in consecutive cycles each consisting of an optimized sequence as follows:
(i) dosing the substrate with a gallium precursor, such as triethylgallium (TEG), to form a layer (e.g., a single monolayer) of gallium precursor on the substrate;
(ii) purging the reaction chamber with an inert gas (e.g., argon gas) to remove any excess of the gallium precursor and/or reaction byproducts from the reaction chamber;
(iii) dosing the substrate with a nitrogen precursor, such as N₂/H₂ forming gas plasma, to react with the layer of gallium precursor, and thereby form a layer (e.g. a single monolayer) of wurtzite gallium nitride (w-GaN) on the substrate;
(iv) purging the reaction chamber with an inert gas (e.g., argon gas) to remove any excess of the nitrogen precursor and/or reaction byproducts from the reaction chamber;
(v) dosing the substrate with an oxygen precursor, such as oxygen plasma, to react with the layer of w-GaN, and thereby form a layer (e.g., a single monolayer) of α-Ga₂O₃ on the substrate; and
(vi) purging the reaction chamber with an inert gas (e.g., argon gas) to remove any excess of the oxygen precursor and/or reaction byproducts from the reaction chamber.

The first four steps (i) to (iv) of this sequence result in a coherent monolayer of w-GaN through which Ga atoms form a stable and highly symmetric scaffold (i.e., possessing 6-fold symmetry). The scaffold steers the oxygen atoms into forming the crystal structure of α-Ga₂O₃ upon oxygen plasma exposure in the remaining two steps (v) and (vi) of the sequence. The cycles are repeated until the desired thickness of α-Ga₂O₃ material is deposited.

The entire deposition is optimized to achieve crystallinity at the low temperature of the substrate 277° C., thereby establishing an energy-efficient fabrication process for growing crystalline Ga₂O₃ films on GaN-compatible substrates on which about one monolayer of heteroepitaxial w-GaN can be initially grown to serve as the template. Once such template is available, the deposition process proceeds in cycles described above to achieve α-Ga₂O₃ through stepwise construction of an atomic scale hexagonal scaffold of Ga atoms while taking advantage of plasma species to transform nitride to oxide at a low thermal budget. Additionally, this GaN-mediated deposition strategy provides a new platform for direct deployment of GaN dopant candidates to Ga₂O₃ during growth and moving toward realization of bipolar Ga₂O₃ electronic devices. Fabrication of Ga₂O₃ devices on GaN-compatible substrates using this deposition strategy also allows for the transfer of pertinent thermal management technologies that are already established for GaN electronics (see below Reference no. 13) which will mitigate the low thermal conductivity of Ga₂O₃ and make devices available that are able to concurrently handle higher power, higher voltage, and higher operating temperatures.

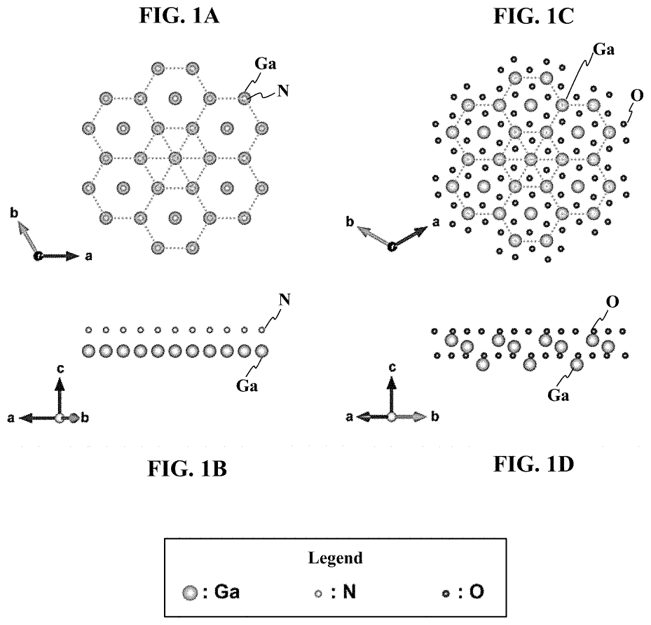

FIGS. 1A and 1C show views along the c-axis of the position of atoms in a monolayer of w-GaN (see below References no. 14 and 15) and a slice of α-Ga₂O₃ (see below References no. 14 and 16), respectively, confirming that the position of Ga atoms in a monolayer of w-GaN coincides with the position of Ga atoms in α-Ga₂O₃ after a 300 in-plane rotation of coordinates. With such an atomic scale scaffold of Ga atoms in place (see dashed lines in FIGS. 1A and 1C as visual references), the highly reactive oxygen plasma can readily interact with nitrogen atoms in the w-GaN monolayer (FIGS. 1A and 1B) and transform it to α-Ga₂O₃(FIGS. 1C and 1D).

The role of ALD in formation of no more than one monolayer of w-GaN in each cycle is a positive enabling factor in establishing a scaffold that is compatible with the position of Ga atoms in α-Ga₂O₃; this indicates the crucial role of controlling the number of deposited monolayers in the success of this GaN-mediated deposition process. Such control may be achieved by a number of epitaxial deposition processes including, but not limited to, different variations of molecular beam epitaxy (MBE), chemical vapor deposition (CVD), pulsed laser deposition (PLD), and atomic layer deposition (ALD). Accordingly, for each cycle, step, or sub-step of the epitaxial deposition process, it may be desirable for each gallium precursor layer to be formed as a single monolayer (i.e., no more than one monolayer), for each w-GaN layer to be formed as a single monolayer (i.e., no more than one monolayer), and for each α-Ga₂O₃ to be formed as a single monolayer. (i.e., no more than one monolayer). It will be understood, however, that practical limits of controlling material deposition may mean that each layer may be an incomplete monolayer (e.g., in ALD where precursor molecules can shadow the surface and do not allow a complete monolayer to form), or may include slightly more than one monolayer (e.g., some variations of MBE and CVD may result in deposition of slightly more than one monolayer depending on the precursors, the reaction conditions, etc.). The present invention is intended to include cases of such slight deviations from a single monolayer and to include adjustments made on the number of repetitions of cycles, steps, or sub-steps to account for those deviations and/or to form up to a theoretically less or more packed layer of material.

As can be seen by comparing FIGS. 1B and 1D, which show views of the same w-GaN monolayer and α-Ga₂O₃ slice, respectively, perpendicular to the c-axis, nitrogen atoms are being removed and oxygen atoms placed in the existing hexagonal scaffold in each cycle, while Ga atoms merely need to move a short distance (<2 Å) along the c-axis (to compare, the Ga—O bond lengths in α-Ga₂O₃ (see below Reference no. 16) are ˜2 Å) to yield α-Ga₂O₃. As will be confirmed by our results, these transformations and displacements are subtle enough to happen at the low deposition temperature of 277° C. using plasma species.

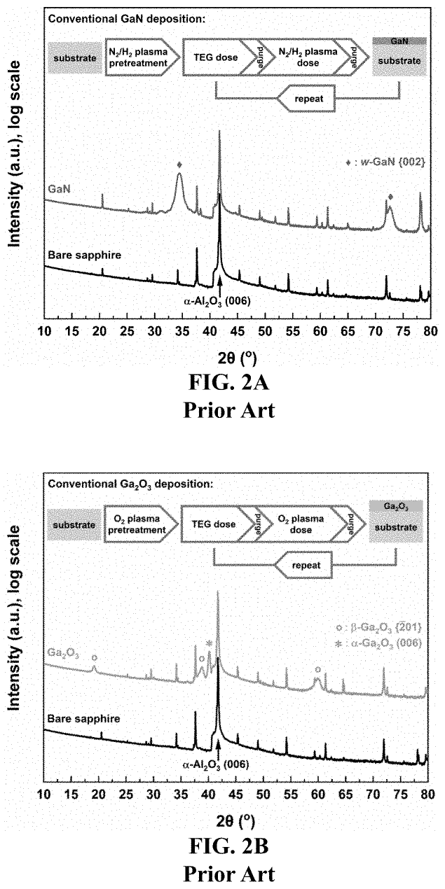

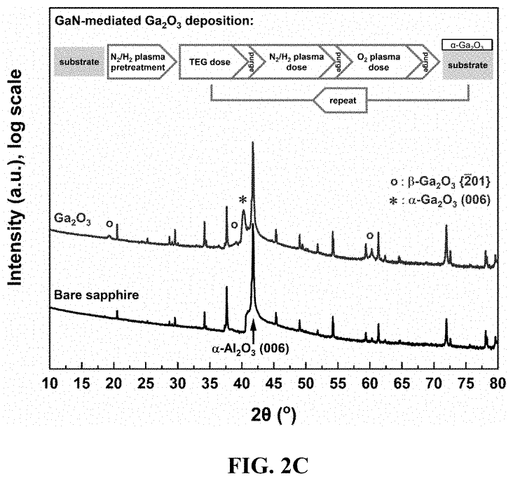

Sapphire, and more particularly c-plane sapphire, may be selected as the non-native substrate due to availability of abundant data for achieving high quality w-GaN on this substrate (see below References no. 17 and 18). As shown in FIG. 2A, depositing a thick (˜22 nm) layer of GaN at 277° C. on c-plane sapphire results in heteroepitaxial w-GaN such that w-GaN (002)∥α-Al₂O₃ (006); this is evident because only these peaks are observed parallel to the surface in out-of-plane XRD scans (note that the corresponding scan of the bare sapphire substrate is included as a reference to better distinguish thin film peaks in the pattern). Previous work (see below Reference no. 17) has confirmed that in addition to this thick GaN layer being a highly oriented heteroepitaxial layer, the first few monolayers of GaN are free from defects which make them an excellent GaN template to start our work with.

FIG. 2C shows a schematic of the GaN-mediated Ga₂O₃ deposition steps used in the present invention, as well as the out-of-plane XRD results for an ˜22 nm film deposited at 277° C. using such approach. As shown in FIG. 2C, an intense peak for α-Ga₂O₃ (006) is observed right next to α-Al₂O₃ (006) peak. No other peaks from α-Ga₂O₃ are present which indicates that the α-Ga₂O₃ film is a highly oriented film with α-Ga₂O₃ (006) planes oriented parallel to the surface. This confirms that α-Ga₂O₃ (006) planes have grown parallel to w-GaN (002) planes. Meanwhile, O—Ga₂O₃ peaks are hardly detectable in FIG. 2C which is indicative of their low population in the film (see the XRD pattern of the bare sapphire substrate to better distinguish thin film peaks in FIG. 2C).

As a reference, depositing Ga₂O₃ directly on sapphire (i.e., without any GaN layers involved) at the same deposition temperature resulted in a mixture of α-Ga₂O₃ and β-Ga₂O₃ in the film; this is shown in FIG. 2B where peaks from α-Ga₂O₃ (006) planes as well as β-Ga₂O₃ (2̅01) family of planes are observed parallel to the surface (the corresponding scan of the bare sapphire substrate is included as a reference to better distinguish thin film peaks in the pattern). Previous results on direct deposition of Ga₂O₃ on sapphire (see below Reference no. 6) show that even though a few monolayers of pseudomorphic α-Ga₂O₃ exist along the sapphire substrate interface, a mixture of α and β phases form in the bulk of such film by using the conventional deposition process. Comparing the observed intensity of β-Ga₂O₃ and α-Ga₂O₃ peaks in FIGS. 2B and 2C, it is estimated that the population of β-Ga₂O₃ in the film is <10% (by ratio of mass of β-Ga₂O₃ to mass of α-Ga₂O₃ and β-Ga₂O₃, collectively) as a result of using the GaN-mediated deposition approach.

These results demonstrate that if the Ga atoms establish a hexagonal arrangement (i.e., an arrangement with a higher degree of symmetry) by forming a monolayer of w-GaN, subsequent exposure to oxygen plasma can successfully interchange the anions while preserving the Ga scaffold thereby leading to formation of a high quality α-Ga₂O₃ layer. This self-regulated crystallization process is favored further by considering that the stacking sequence of atoms in both w-GaN and α-Ga₂O₃ is of the hexagonal closest packing (hcp) type with both N anions in w-GaN and O anions in α-Ga₂O₃ being surrounded by 4 Ga atoms (i.e., both anions have a coordination number of 4), while β-Ga₂O₃ has the stacking sequence of a distorted cubic closest packing (ccp) type with coordination number of 6 for two of the O anions and 4 for one of the O anions. Therefore, even though β-Ga₂O₃ domains are demonstrated to form in the absence of structural restrictions to atomic diffusion in the reference Ga₂O₃ film (see FIG. 2B, and below Reference no. 6), presence of a hexagonal framework of Ga atoms by using a GaN-mediated deposition strategy enables the ability to control the crystallinity of the film in situ and to achieve α-Ga₂O₃ while minimizing β-Ga₂O₃ inclusions.

Using such a hexagonal scaffold at the atomic scale also offers the potential to provide a means by which metal dopant atoms (especially those that are known to be compatible with w-GaN) can be incorporated into the GaN layer in situ (see, for example, below References no. 19 and 20 for methods to incorporate dopant atoms into ALD films in situ), subsequently oxidized, and thereby be embedded in the α-Ga₂O₃ structure during the deposition.

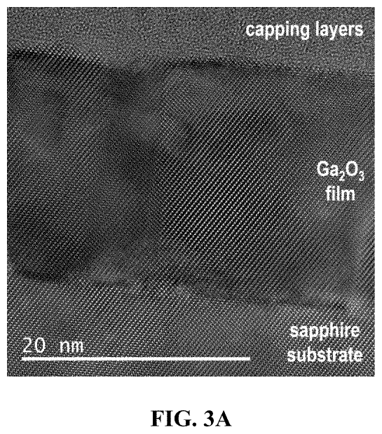

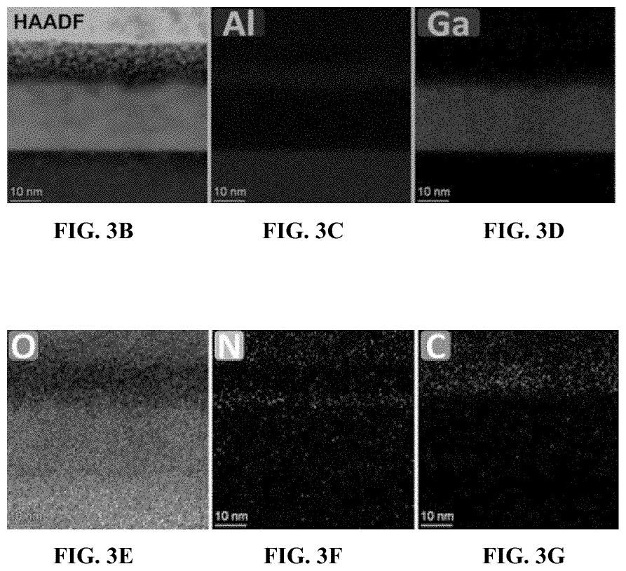

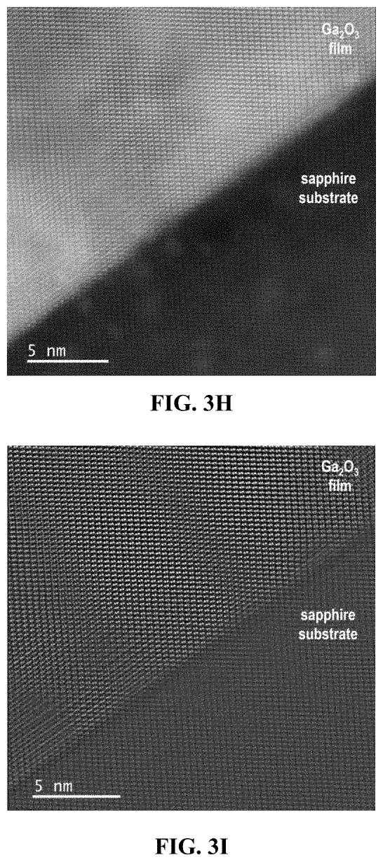

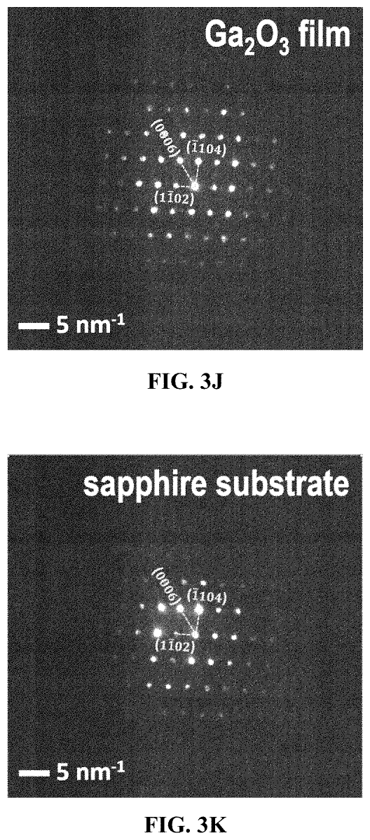

To investigate the structure of the α-Ga₂O₃ film deposited by the GaN-mediated approach further, cross-section TEM analysis was performed, and representative results are shown in FIGS. 3A through 3K. The TEM analyses show that the entire film (˜22 nm) is crystalline (see, for example, the HRTEM image in FIG. 3A, and the STEM images in FIGS. 3H and 3I) and confirm the crystal structure to be predominantly α-Ga₂O₃ such that α-Ga₂O₃(006) planes are parallel to the surface (also see the electron diffraction patterns of focused regions of the film and the substrate in FIGS. 3J and 3K, respectively). It is worth noting that because α-Ga₂O₃ is isostructural to the sapphire substrate (both having the corundum structure) with <5% lattice mismatch (see below References no. 6, 16, and 21), the diffraction patterns of these two materials are expected to be very similar if their crystals are oriented the same way. This is consistent with the results presented in FIGS. 3J and 3K. In addition to these figures, line profiles (not shown) of nano-beam electron diffraction patterns, which were collected to show the diffraction patterns at several locations of the lamella, confirm the predominant presence of the α-Ga₂O₃ phase. Energy dispersive X-ray spectroscopy (EDS) analyses, in FIGS. 3B to 3G, show the low amount of impurities (both C and N) in the film and further prove the high quality of the α-Ga₂O₃ film. The presence of trace amounts (near zero ppm) of N in the film, as seen in FIG. 3F, and as may be quantified by other compositional analysis and/or characterization methods, may be attributed to the use of the GaN-mediated Ga₂O₃ deposition strategy of the present invention.

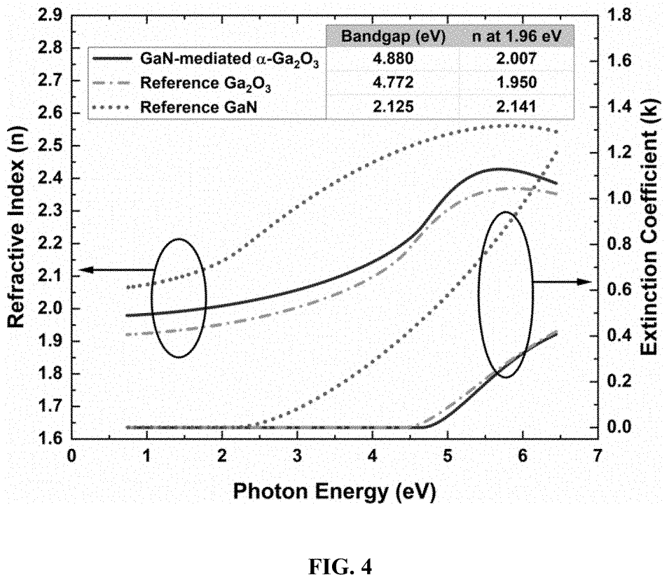

In addition to crystal structure, investigating optical properties of thin films can provide insights into the quality and performance of the material. To that end, in-situ ellipsometry measurements were performed on the GaN-mediated in-situ oxidized Ga₂O₃ film, as well as a reference Ga₂O₃ film with no GaN layers involved during its deposition, and a reference GaN film. In all cases, the substrate was c-plane sapphire, and the measurements were performed after 450 doses of TEG (which resulted in an ˜22 nm α-Ga₂O₃ film deposited by using the GaN-mediated approach, as well as an ˜26 nm reference α-Ga₂O₃/β-Ga₂O₃ mixed-phase film, and an ˜22 nm reference GaN film, respectively—the difference in thickness of the two Ga₂O₃ films is consistent with the fact that β-Ga₂O₃ has a larger molar volume than α-Ga₂O₃ (see below References no. 8 and 9); thus, inclusion of β-Ga₂O₃ domains in the film results in a thicker film for a constant number of TEG doses). As shown in FIG. 4, the values of extinction coefficient (k) for the two Ga₂O₃ films are remarkably similar to each other and different from the GaN film. Both Ga₂O₃ films have larger bandgaps compared to the reference GaN film (see the energy at which k starts to deviate from zero or the listed values included in FIG. 4); meanwhile, the α-Ga₂O₃ film deposited by using the GaN-mediated approach of the present invention has a slightly larger bandgap compared to the reference α-Ga₂O₃/β-Ga₂O₃ mixed-phase film. FIG. 4 also shows that while the refractive index (n) for the two oxide films are both smaller than GaN (as expected), using the GaN-mediated deposition strategy of the present invention results in a Ga₂O₃ film with larger refractive index values over the entire measured spectral range. This observation is consistent with the crystal structure of the films noting that α-Ga₂O₃ has a higher atomic packing density (i.e., smaller molar volume) than β-Ga₂O₃, and thus is expected to have a larger refractive index compared to the β phase (see below References no. 8 and 9). As seen in FIG. 4, specifically at the photon energy of 1.96 eV (equivalent to 632.8 nm), the GaN-mediated α-Ga₂O₃ film has a high refractive index value of 2.007, which is higher than the reported value of 1.97 for bulk β-Ga₂O₃ wafers (see below Reference no. 22) as well as other literature reports for Ga₂O₃(see below Reference no. 8).

### Experimental Example

Depositions were done at 277° C. on single-side polished (Rₐ<0.3 nm) prime quality c-plane sapphire wafers (see below Reference no. 6 for detailed specifications of the wafers) by using a Kurt J. Lesker ALD 150-LX™ system equipped with a remote inductively coupled plasma (ICP) source and a load lock. The error in determining the actual deposition temperatures was ±3° C. The pressure of the reactor was ˜1.1 Torr with ˜1000 sccm continuous flow of argon. In addition, 60 sccm oxygen or N₂/H₂ forming gas was introduced to the reactor during plasma exposures with ˜600 W forward power. This setup is also explained in detail elsewhere (see below References no. 6 and 23). Triethylgallium, TEG, (Strem Chemicals, Inc.) was electronic grade (99.9999% Ga) in a stainless steel Swagelok™ cylinder assembly which was not heated during the depositions; all other gases (argon, oxygen, and forming gas) were of ultrahigh purity (99.999%, Praxair Canada, Inc.). Substrates were exposed to 60 s plasma to remove contamination and pretreat the surface prior to deposition. Reference GaN depositions were done by using a recipe consisting of 0.1 s TEG dose, 3 s argon purge, 15 s N₂/H₂ forming gas plasma dose, and 2 s argon purge. Reference Ga₂O₃ depositions were done by using a recipe consisting of 0.1 s TEG dose, 20 s argon purge, 10 s oxygen plasma dose, and 12 s argon purge (reducing the two purge times down to 3 s and 2 s, respectively, did not change the deposition results for the reference Ga₂O₃). GaN-mediated Ga₂O₃ depositions were done by using a recipe consisting of 0.1 s TEG dose, 6 s argon purge, 15 s N₂/H₂ forming gas plasma dose, 13 s argon purge, 1.5 s oxygen plasma dose, and 10 s argon purge (the N₂/H₂ forming gas plasma dose time was chosen to ensure completion of GaN formation reactions while the oxygen plasma dose time was chosen to ensure complete conversion of nitride to oxide using GaN and Ga₂O₃ enthalpies of formation (see below Reference no. 24) as guides).

Ellipsometry measurements were done by using a J. A. Woollam M-2000DI™ spectroscopic ellipsometer, permanently mounted on the reactor at an incident angle of 70°, in the spectral range of 0.73-6.40 eV (equivalent to 190-1700 nm) at intervals less than 0.05 eV. Ellipsometry data analysis was done by using CompleteEASE™ software. Thickness and optical constants of the films were obtained based on Tauc-Lorentz modelling of the ellipsometry data (see below Reference no. 6 for detailed explanation of the modelling procedure).

Out-of-plane coupled 1D XRD scans were performed by using a Rigaku Ultima-IV™ diffractometer equipped with a cobalt source, a D/Tex™ ultrahigh-speed position sensitive detector, and a K-β filter at a scan rate of 2°/min and 0.02° steps (which is equivalent to 0.6 s/step exposure). The patterns were converted to copper wavelength for easier comparison with the literature.

Cross-section TEM lamella was prepared by low-energy ion polishing (to minimize damage) by using a ThermoFisher Helios Hydra DualBeam™ plasma-focused-ion-beam (PFIB) system. HRTEM images were obtained by using a Titan 80-300™ HRTEM instrument. Atomic resolution STEM analyses (including STEM images, EDS maps, and nano-beam diffraction patterns) were performed by using a Thermo Scientific Themis Z™ S/TEM instrument equipped with 4 windowless EDS detectors arranged symmetrically around the sample to allow EDS mapping of light elements such as C, N, and O.

FIGS. 2A, 2B and 2C show out-of-plane coupled XRD patterns and schematic of the deposition steps for conventional GaN deposition (FIG. 2A), conventional Ga₂O₃ deposition (FIG. 2B) and GaN-mediated Ga₂O₃ deposition in accordance with the present invention (FIG. 2C). In these Figures, the XRD pattern of the bare sapphire substrate is included as a reference to better distinguish thin film peaks in the patterns.

FIGS. 3A through 3K show transmission electron microscopy (TEM) analysis results for a GaN-mediated in-situ oxidized Ga₂O₃ film of the present invention, as follows.

FIG. 3A is a high-resolution transmission electron microscopy (HRTEM) image.

FIGS. 3B to 3G are energy-dispersive X-ray spectroscopy (EDS) intensity maps obtained in scanning transmission electron microscopy (STEM) mode, without background subtraction obtained with a high-angle annular dark-field (HAADF) imaging detector (FIG. 3B), and with background subtraction obtained with EDS detectors to show spectra of aluminum (FIG. 3C), gallium (FIG. 3D), oxygen (FIG. 3E), nitrogen (FIG. 3F), and carbon (FIG. 3G).

FIG. 3H is an atomic resolution STEM image obtained with a HAADF imaging detector.

FIG. 3I is the same image shown in FIG. 3H after using a combination of high-pass and radial Wiener filters to highlight atomic columns.

FIG. 3J is a nano-beam electron diffraction pattern of the Ga₂O₃ film.

FIG. 3K is a nano-beam electron diffraction pattern of the sapphire substrate.

FIG. 4 shows optical constants of the GaN-mediated in-situ oxidized Ga₂O₃ film of the present invention, compared to two reference films after equal number of triethylgallium (TEG) doses. The values of bandgap and refractive index at the photon energy of 1.96 eV (corresponding to the wavelength of 632.8 nm) are listed for comparison.

Interpretation.

The corresponding structures, materials, acts, and equivalents of all means or steps plus function elements in the claims appended to this specification are intended to include any structure, material, or act for performing the function in combination with other claimed elements as specifically claimed.

References in the specification to “one embodiment”, “an embodiment”, etc., indicate that the embodiment described may include a particular aspect, feature, structure, or characteristic, but not every embodiment necessarily includes that aspect, feature, structure, or characteristic. Moreover, such phrases may, but do not necessarily, refer to the same embodiment referred to in other portions of the specification. Further, when a particular aspect, feature, structure, or characteristic is described in connection with an embodiment, it is within the knowledge of one skilled in the art to affect or connect such module, aspect, feature, structure, or characteristic with other embodiments, whether or not explicitly described. In other words, any module, element or feature may be combined with any other element or feature in different embodiments, unless there is an obvious or inherent incompatibility, or it is specifically excluded.

It is further noted that the claims may be drafted to exclude any optional element. As such, this statement is intended to serve as antecedent basis for the use of exclusive terminology, such as “solely,” “only,” and the like, in connection with the recitation of claim elements or use of a “negative” limitation. The terms “preferably,” “preferred,” “prefer,” “optionally,” “may,” and similar terms are used to indicate that an item, condition or step being referred to is an optional (not required) feature of the invention.

The singular forms “a,” “an,” and “the” include the plural reference unless the context clearly dictates otherwise. The term “and/or” means any one of the items, any combination of the items, or all of the items with which this term is associated. The phrase “one or more” is readily understood by one of skill in the art, particularly when read in context of its usage.

The term “about” or “˜” can refer to a variation of 5%, f 10%, f 20%, or 25% of the value specified. For example, “about 50” percent can in some embodiments carry a variation from 45 to 55 percent. For integer ranges, the term “about” or “˜” can include one or two integers greater than and/or less than a recited integer at each end of the range. Unless indicated otherwise herein, the term “about” or “˜” is intended to include values and ranges proximate to the recited range that are equivalent in terms of the functionality of the composition, or the embodiment.

As will be understood by one skilled in the art, for any and all purposes, particularly in terms of providing a written description, all ranges recited herein also encompass any and all possible sub-ranges and combinations of sub-ranges thereof, as well as the individual values making up the range, particularly integer values. A recited range includes each specific value, integer, decimal, or identity within the range. Any listed range can be easily recognized as sufficiently describing and enabling the same range being broken down into at least equal halves, thirds, quarters, fifths, or tenths. As a non-limiting example, each range discussed herein can be readily broken down into a lower third, middle third and upper third, etc.

As will also be understood by one skilled in the art, all language such as “up to”, “at least”, “greater than”, “less than”, “more than”, “or more”, and the like, include the number recited and such terms refer to ranges that can be subsequently broken down into sub-ranges as discussed above. In the same manner, all ratios recited herein also include all sub-ratios falling within the broader ratio.

### REFERENCES

The following publications cited herein are indicative of the level of one skilled in the art and are incorporated herein by reference in their entireties, except for any subject matter disclaimers or disavowals, and except to the extent that the incorporated material is inconsistent with the express disclosure herein, in which case the language in this disclosure controls.
1. Mastro, M. A.; Kuramata, A.; Calkins, J.; Kim, J.; Ren, F.; Pearton, S. J. Perspective—Opportunities and Future Directions for Ga₂O₃. ECSJ. Solid State Sci. Technol. 2017, 6, P356-P359.
2. Higashiwaki, M.; Sasaki, K.; Kuramata, A.; Masui, T.; Yamakoshi, S. Development of Gallium Oxide Power Devices. Phys. Status Solidi A 2014, 211, 21-26.
3. Pearton, S. J.; Yang, J.; Cary, P. H.; Ren, F.; Kim, J.; Tadjer, M. J.; Mastro, M. A. A Review of Ga₂O₃ Materials, Processing, and Devices. Appl. Phys. Rev. 2018, 5, 011301.
4. Pearton, S. J.; Ren, F.; Tadjer, M.; Kim, J. Perspective: Ga₂O₃ for Ultra-High Power Rectifiers and MOSFETS. J. Appl. Phys. 2018, 124, 220901.
5. Higashiwaki, M.; Jessen, G. H. Guest Editorial: The Dawn of Gallium Oxide Microelectronics. Appl. Phys. Lett. 2018, 112, 060401.
6. Rafie Borujeny, E.; Sendetskyi, O.; Fleischauer, M. D.; Cadien, K. C. Low Thermal Budget Heteroepitaxial Gallium Oxide Thin Films Enabled by Atomic Layer Deposition. ACS Appl. Mater. Interfaces 2020, 12, 44225-44237.
7. Kyrtsos, A.; Matsubara, M.; Bellotti, E. On the Feasibility of p-Type Ga2O3. Appl. Phys. Lett. 2018, 112, 032108.
8. He, H.; Orlando, R.; Blanco, M. A.; Pandey, R.; Amzallag, E.; Baraille, I.; Rérat, M. First-Principles Study of the Structural, Electronic, and Optical Properties of Ga₂O₃ in its Monoclinic and Hexagonal Phases. Phys. Rev. B 2006, 74, 195123.
9. Zinkevich, M.; Aldinger, F. Thermodynamic Assessment of the Gallium-Oxygen System. J. Am. Ceram. Soc. 2004, 87, 683-691.
10. Kukushkin, S. A.; Osipov, A. V.; Bessolov, V. N.; Medvedev, B. K.; Nevolin, V. K.; Tcarik, K. A. Substrates for Epitaxy of Gallium Nitride: New Materials and Techniques. Rev. Adv. Mater. Sci. 2008, 17, 1-32.
11. Villora, E. G.; Shimamura, K.; Kitamura, K.; Aoki, K.; Ujiie, T. Epitaxial Relationship Between Wurtzite GaN and β-Ga2O3. Appl. Phys. Lett. 2007, 90, 234102.
12. Amano, H.; Baines, Y.; Beam, E.; Borga, M.; Bouchet, T.; Chalker, P. R.; Charles, M.; Chen, K. J.; Chowdhury, N.; Chu, R.; De Santi, C.; De Souza, M. M.; Decoutere, S.; Di Cioccio, L.; Eckardt, B.; Egawa, T.; Fay, P.; Freedsman, J. J.; Guido, L.; Häberlen, O.; Haynes, G.; Heckel, T.; Hemakumara, D.; Houston, P.; Hu, J.; Hua, M.; Huang, Q.; Huang, A.; Jiang, S.; Kawai, H.; Kinzer, D.; Kuball, M.; Kumar, A.; Lee, K. B.; Li, X.; Marcon, D.; MArz, M.; McCarthy, R.; Meneghesso, G.; Meneghini, M.; Morvan, E.; Nakajima, A.; Narayanan, E. M. S.; Oliver, S.; Palacios, T.; Piedra, D.; Plissonnier, M.; Reddy, R.; Sun, M.; Thayne, I.; Torres, A.; Trivellin, N.; Unni, V.; Uren, M. J.; Van Hove, M.; Wallis, D. J.; Wang, J.; Xie, J.; Yagi, S.; Yang, S.; Youtsey, C.; Yu, R.; Zanoni, E.; Zeltner, S.; Zhang, Y. The 2018 GaN Power Electronics Roadmap. J. Phys. D: Appl. Phys. &nbsp; 2018, 51, 163001.
13. Guggenheim, R.; Rodes, L. Roadmap Review for Cooling High-Power GaN HEMT Devices. 2017 IEEE International Conference on Microwaves, Antennas, Communications and Electronic Systems (COMCAS) 2017, 1-6.
14. Momma, K.; Izumi, F. VESTA 3 for Three-Dimensional Visualization of Crystal, Volumetric and Morphology Data. J. Appl. Crystallogr. 2011, 44, 1272-1276.
15. Juza, R.; Hahn, H. Über die Kristallstrukturen von Cu3N, GaN und InN Metallamide und Metallnitride. Z. Anorg. Allg. Chem. 1938, 239, 282-287.
16. Marezio, M.; Remeika, J. P. Bond Lengths in the α-Ga₂O₃ Structure and the High-Pressure Phase of Ga2-xFexO3. J. Chem. Phys. 1967, 46, 1862-1865.
17. Motamedi, P.; Dalili, N.; Cadien, K. A Route to Low Temperature Growth of Single Crystal GaN on Sapphire. J. Mater. Chem. C 2015, 3, 7428-7436.
18. Motamedi, P.; Cadien, K. Structure-Property Relationship and Interfacial Phenomena in GaN Grown on C-Plane Sapphire via Plasma-Enhanced Atomic Layer Deposition. RSC Adv. 2015, 5, 57865-57874.
19. Liang, Y.; Towe, E. Progress in Efficient Doping of High Aluminum-Containing Group III-Nitrides. Appl. Phys. Rev. 2018, 5, 011107.
20. Gao, Z.; Banerjee, P. Review Article: Atomic Layer Deposition of Doped ZnO Films. J. Vac. Sci. Technol. A 2019, 37, 050802.
21. Pauling, L.; Hendricks, S. B. The Crystal Structures of Hematite and Corundum. J. Am. Chem. Soc. 1925, 47, 781-790.
22. Tamura Corporation β-Ga2O3 Substrates. https://www.tamuracorp.com/products/gao/index.html. Last accessed: October, 2020.
23. Afshar, A. Materials Characterization and Growth Mechanisms of ZnO, ZrO2, and HfO2 Deposited by Atomic Layer Deposition, University of Alberta, PhD Thesis, 2014.
24. Yaws, C. L. Yaws' Handbook of Thermodynamic Properties for Hydrocarbons and Chemicals, Chapter 5: Enthalpies of Formation of Solids—Table for Elements and Inorganic Compounds. 2009.

1. A method for forming a thin film comprising alpha-gallium oxide (α-Ga₂O₃) on a GaN-compatible substrate, the method using an epitaxial deposition process comprising the steps of:
(a) forming a layer of wurtzite gallium nitride (w-GaN) on the substrate; and
(b) reacting the layer of w-GaN with an oxygen precursor to form a layer of α-Ga₂O₃ on the substrate.

2. The method of claim 1, further comprising repeating steps (a) and (b) to form one or more additional layers of α-Ga₂O₃ on the substrate.

3. The method of claim 1, wherein the layer of w-GaN is a single monolayer of w-GaN.

4. The method of claim 1, wherein the layer of α-Ga₂O₃ is a single monolayer of α-Ga₂O₃.

5. The method of claim 1, wherein the GaN-compatible substrate is a non-native substrate.

6. The method of claim 5, wherein the non-native substrate comprises a sapphire.

7. The method of claim 6, wherein the sapphire is c-plane sapphire.

8. The method of claim 1, wherein the thin film comprises less than 10% β-Ga₂O₃, by ratio of mass of β-Ga₂O₃ to mass of α-Ga₂O₃ and β-Ga₂O₃, collectively.

9. The method of claim 1, wherein the epitaxial deposition process comprises an atomic layer deposition process, and wherein step (a) comprises the sequential sub-steps of:
(i) contacting the substrate with a gallium precursor to form a layer of gallium precursor on the substrate; and
(ii) reacting the layer of gallium precursor with a nitrogen precursor to form the layer of wurtzite gallium nitride (w-GaN) on the substrate.

10. The method of claim 9, wherein the layer of gallium precursor is a single monolayer of gallium precursor.

11. The method of claim 9, wherein the gallium precursor comprises triethylgallium (TEG) gas.

12. The method of claim 9, wherein the nitrogen precursor comprises a N₂/H₂ forming gas plasma.

13. The method of claim 9, wherein the oxygen precursor comprises an oxygen plasma.

14. The method of claim 9, wherein sub-step (i) further comprises, after forming the layer of gallium precursor on the substrate, purging the reaction chamber with an inert gas to remove any excess of the gallium precursor and/or reaction byproducts from the reaction chamber.

15. The method of claim 9, wherein sub-step (ii) further comprises, after forming the layer of w-GaN on the substrate, purging the reaction chamber with an inert gas to remove any excess of the nitrogen precursor and/or reaction byproducts from the reaction chamber.

16. The method of claim 9, wherein step (b) further comprises, after forming the layer of α-Ga₂O₃ on the substrate, purging the reaction chamber with an inert gas to remove any excess of the oxygen precursor and/or reaction byproducts from the reaction chamber.

17. The method of claim 9, wherein:
sub-step (i) comprises providing a 0.1 s pulsed dose of the gallium precursor comprising triethylgallium (TEG) gas into the reaction chamber, followed by a 6 s argon purge gas into the reaction chamber to remove any excess of the gallium precursor and/or reaction byproducts from the reaction chamber;
sub-step (ii) comprises providing a 15 s pulsed dose of the nitrogen precursor comprising a N₂/H₂ forming gas plasma into the reaction chamber, followed by a 13 s argon purge gas into the reaction chamber to remove any excess of the nitrogen precursor and/or reaction byproducts from the reaction chamber; and
step (b) comprises providing 1.5 s pulsed dose of the oxygen precursor comprising an oxygen plasma into the reaction chamber, followed by a 10 s argon purge gas into the reaction chamber to remove any excess of the oxygen precursor and/or reaction byproducts from the reaction chamber.

18. The method of claim 1, wherein the method is performed at a temperature of less than about 300° C.

19. A thin film of α-Ga₂O₃ formed by atomic layer deposition, wherein the thin film comprises less than 10% β-Ga₂O₃, by ratio of mass of β-Ga₂O₃ to mass of α-Ga₂O₃ and β-Ga₂O₃, collectively.

20. The thin film of claim 19 formed by the method of claim 1.
